(19) United States
(12) Patent Application Publication
(10) Pub. No.: US 2017/0053930 A1
(43) Pub. Date: Feb. 23, 2017

(54) SEMICONDUCTOR DEVICE HAVING A METAL OXIDE METAL (MOM) CAPACITOR AND A PLURALITY OF SERIES CAPACITORS AND METHOD FOR FORMING

(71) Applicant: FREESCALE SEMICONDUCTOR, INC., AUSTIN, TX (US)

(72) Inventors: ERWIN J. PRINZ, AUSTIN, TX (US); KURT H. JUNKER, DRIPPING SPRINGS, TX (US)

(21) Appl. No.: 14/828,723

(22) Filed: Aug. 18, 2015

(51) Int. Cl. H01L 27/115; H01L 29/423; H01L 49/02; H01L 27/02; H01L 27/118

(52) U.S. Cl. CPC H01L 27/11573; H01L 27/0222; H01L 27/11807; H01L 27/11568; H01L 28/60; H01L 29/42344; H01L 2027/11872

(57) ABSTRACT

A capacitor module includes a semiconductor substrate of a first polarity. The substrate includes a deep well of a second polarity, a first well of the first polarity over the deep well, a second well of the second polarity over at least a portion of the deep well, a first capacitor including the first well as a first electrode, a dielectric layer over the first electrode, and an electrically conductive layer as a second electrode over the dielectric layer, and a second capacitor including the second well as a first electrode, a dielectric layer over the first electrode, and an electrically conductive layer as a second electrode over the dielectric layer. The first capacitor is coupled in series with the second capacitor. A metal-oxide-metal (MOM) capacitor overlays and is coupled in parallel with the first and second capacitors.

### BACKGROUND

Field

This disclosure relates generally to semiconductor processing, and more specifically, to a semiconductor device having a metal oxide metal (MOM) capacitor and a plurality of series capacitors and method for forming.

Related Art

As technology advances, it is desirable to integrate a greater variety of circuit types. For example, in a single integrated circuit, it may be desirable to integrate high voltage logic devices with low voltage logic devices along with embedded nonvolatile memory. Nonvolatile memories (NVMs) typically require a high voltage charge pump which generates a high voltage required to perform operations on the memory cells of the NVM. A primary component of a high voltage charge pump is a high voltage capacitor. If the high voltage capacitor is integrated with the high and low voltage logic devices, it is desirable to use the available processes used in forming the logic devices. However, if a high voltage capacitor is formed using such processes, a large area is required to form a capacitor having the desired capacitance per area. It is desirable to reduce circuit area while still maintaining reliability of the high voltage capacitor. Therefore, a need exists for an improved high voltage capacitor which may be integrated with logic devices.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates, in diagrammatic form, a plan view of an integrated circuit in accordance with one embodiment of the present invention.

FIGS. 2-10 illustrate, in cross-sectional form, a semiconductor structure having a high voltage capacitor region, a high voltage logic region, and a low voltage logic region at various processing stages, in accordance with one embodiment of the present invention.

FIG. 11 illustrates, in cross-sectional form, a semiconductor structure having a high voltage capacitor region and a low voltage memory region, in accordance with one embodiment of the present invention.

FIG. 12 illustrates a top-down view of a metal oxide metal (MOM) capacitor, in accordance with one embodiment of the present invention.

FIG. 13 illustrates, in schematic view, a high voltage capacitive structure, in accordance with one embodiment of the present invention.

### DETAILED DESCRIPTION

To efficiently embed NVM with logic devices, an area efficient high voltage capacitor module is needed for the charge pump. In one embodiment, the capacitor module includes a metal oxide metal (MOM) capacitor formed over and coupled in parallel with at least two series connected capacitors formed on and within the substrate. The at least two series connected capacitors see only a fraction of the high voltage, and the total capacitance is provided by the combination of all the capacitors. By stacking the MOM capacitor over the at least two series connected capacitors, sufficient capacitance is achieved in an area efficient manner for the high voltages required for the NVM. Further efficiencies are achieved when integrating the capacitor module with other devices, such as high voltage logic devices or memory devices, by using available layers in the formation of these other devices to form the dielectrics of the series connected capacitors.

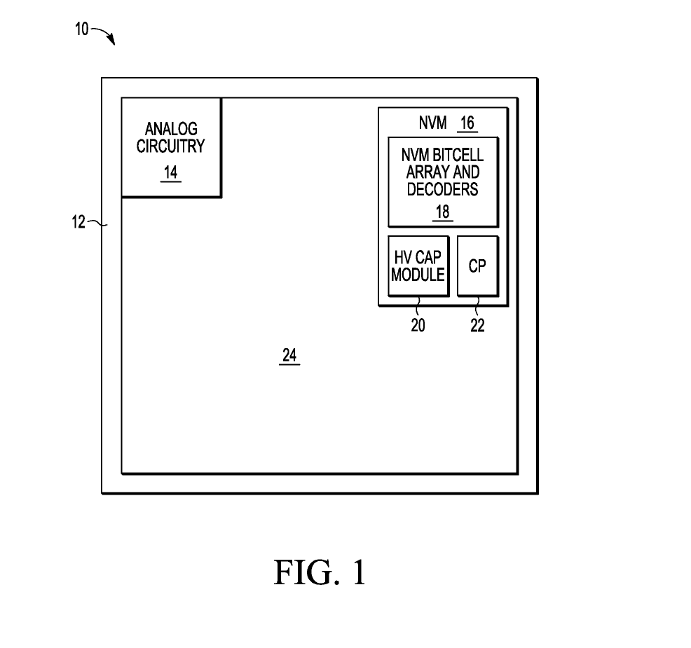

FIG. 1 illustrates a plan view of an integrated circuit (IC) 10 in accordance with one embodiment of the present invention. In one embodiment, IC 10 is a system on a chip (SOC) and thus may be referred to as a processing SOC. IC 10 includes an input/output (I/O) ring 12 surrounding circuitry, in which the circuitry includes analog circuitry 14, an NVM 16, and logic circuitry 24. NVM 16 includes an NVM bitcell array and associated decoders 18, a high voltage (HV) capacitor module 20 and a charge pump 22. Charge pump 22 is coupled between capacitor module 20 and the NVM bitcell array. The areas within ring 12, outside analog circuitry 14 and NVM 16, includes logic circuitry 24, which may include a sea of gates used to implement a variety of functions of IC 10. In one embodiment, logic circuitry 24 includes low voltage (LV) logic gates, I/O ring 12 includes high voltage (HV) logic gates, and analog circuitry may include both LV and HV devices. In the illustrated embodiment, NVM 16 is embedded within IC 10 such that the resulting SoC includes nonvolatile memory. The circuit area required for NVM 16 affects the total size of IC 10. Therefore, it is desirable to control the area of NVM 16 so as not to increase the size of IC 10. The area of NVM 16 can be minimized, in part, by reducing the area required for HV cap module 20. Furthermore, processing cost efficiencies in manufacturing IC 10 can be achieved by using existing steps and processes used in forming circuitry 14 and 24 to form HV cap module 20.

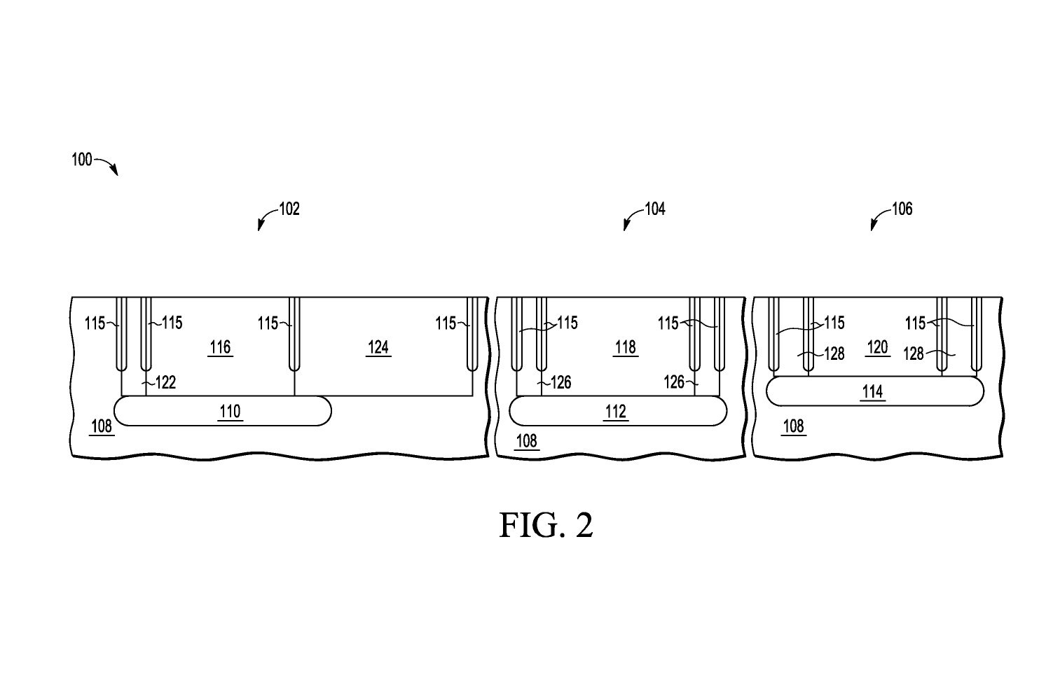

FIG. 2 illustrates, in cross-sectional form, a semiconductor structure 100 at a processing stage, in accordance with one embodiment of the present invention. Structure 100 includes a semiconductor substrate 108 having a HV capacitor region 102, a HV logic region 104, and a LV logic region 106. In one embodiment, HV capacitor region 102 is used to form a HV capacitor module of NVM 16, while regions 104 and 106 may be located within other portions of IC 10. For example, HV logic region 104 may be a region within ring 12 or analog circuitry 14 and LV logic region may be a region within logic circuitry 24. Substrate 108 can be any semiconductor material or combinations of materials, such as gallium arsenide, silicon germanium, silicon-on-insulator (SOI), silicon, monocrystalline silicon, the like, and combinations of the above. Substrate 108 includes a p-type well (PW) 116, an n-type well (NW) 124, an n-type well (NW) 122, and a deep n-type well (DNW) 110 in region 102. Substrate 108 includes a p-type well (PW) 118, an n-type well (NW) 126, and a deep n-type well (DNW) 112 in region 104. Substrate 108 includes a LV p-type well (LVPW) 120, a LV n-type well (LVNW) 128, and a LV deep n-type well (LVDNW) 114 in region 106. Substrate 108 also includes trench isolation regions 115 located at boundaries between wells and between wells and the substrate, such as between NW 122 and substrate 108, between NW 122 and PW 116, between PW 116 and NW 124, between NW 124 and substrate 108, between NW 126 and substrate 108, between NW 126 and PW 118, between LVNW 128 and substrate 108, between LVNW 128 and LVPW 120. Note that trench isolation regions 115 may extend less into substrate 108 than the NWs or PWs.

In an alternate embodiment, DNW 110 may extend under all of NW 124, but at least underlies the junction between PW 116 and NW 124. In the illustrated embodiment, PW 116 and NW 124 are directly adjacent with each other, such that they physically contact each other. In an alternate embodiment, PW 116 and NW 124 may be adjacent each other but spaced apart, in which a portion of substrate 108 is located between the two wells. In this embodiment, a trench isolation region is formed at the boundaries between the trenches and the portion of substrate 108 between the two wells. Also, in this embodiment, a portion of NW 122 may be present on the opposite side of PW 116 (similar to NW 126 which surrounds PW 118). In another alternate embodiment, DNW 112 in region 104 may not be present. Formation of the n-type wells, p-type wells, and deep wells may be formed using known masking and implanting techniques. Note that each of the well regions may be referred to as a doped well region. Also note that substrate 108 may be doped. For example, substrate 108 may be doped to be a p-type substrate.

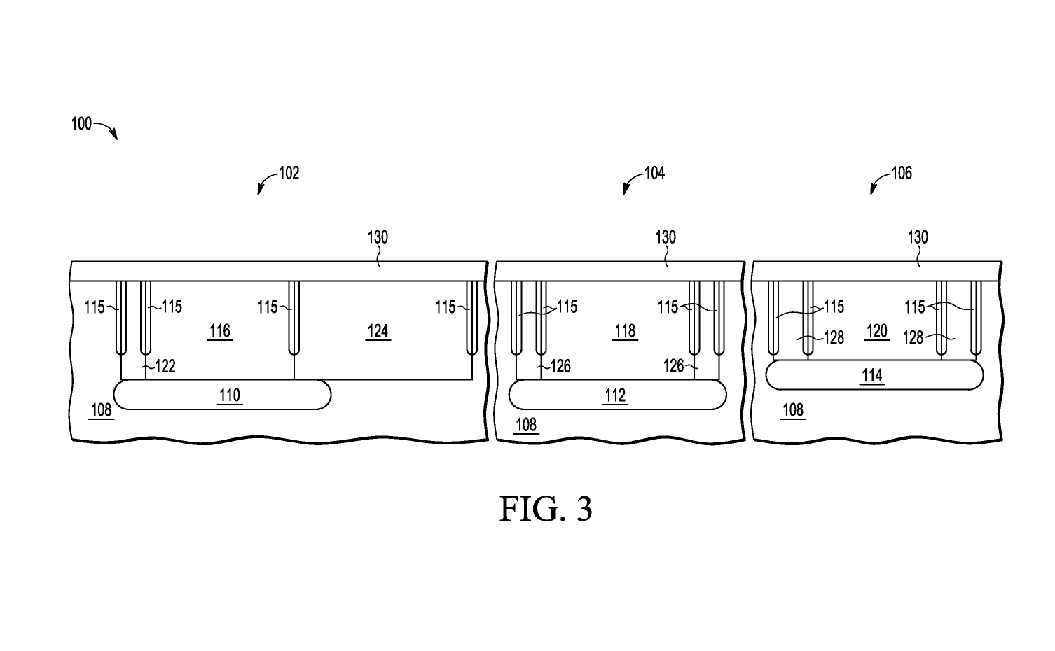

FIG. 3 illustrates, in cross-sectional form, semiconductor structure 100 at a subsequent processing stage, in accordance with one embodiment of the present invention. A dielectric layer 130 is formed over substrate 108. In one embodiment, dielectric layer 130 is an oxide layer which may be grown or blanket deposited over substrate 108. Therefore, dielectric layer 130 is simultaneously formed in regions 102, 104, and 106.

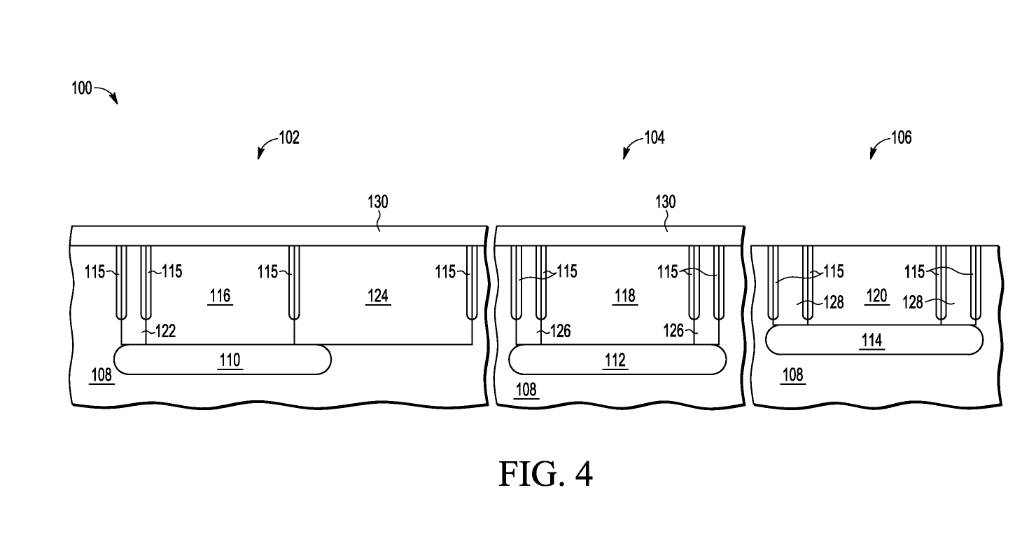

FIG. 4 illustrates, in cross-sectional form, semiconductor structure 100 at a subsequent processing stage, in accordance with one embodiment of the present invention. Dielectric layer 130 is removed from LV logic region 106. Dielectric layer 130 remains in both HV cap region 102 and HV logic region 104.

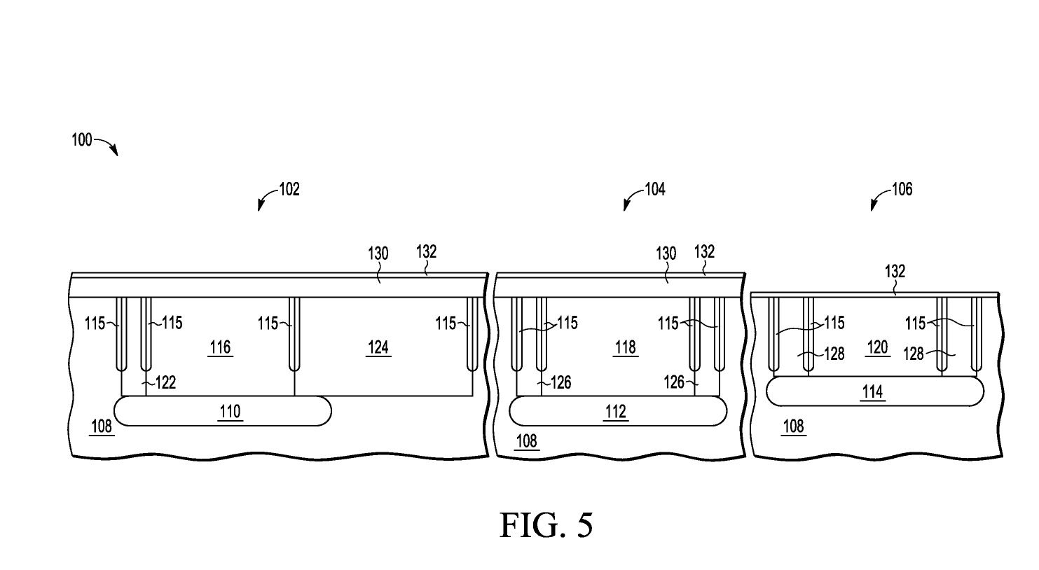

FIG. 5 illustrates, in cross-sectional form, semiconductor structure 100 at a subsequent processing stage, in accordance with one embodiment of the present invention. A high K dielectric layer 132 is deposited over substrate 108 in regions 102, 104, and 106. In regions 102 and 104, it is deposited over dielectric layer 130. In region 106, it is deposited onto substrate 108 since dielectric layer 130 has been removed. Therefore, high K dielectric layer 132 is also simultaneously formed in regions 102, 104, and 106. High K dielectric layer includes a dielectric material having a high dielectric constant K. A high K refers to a dielectric constant that is greater than the dielectric constant of silicon dioxide. Examples of high K dielectric materials include hafnium dioxide (HfO₂), hafnium silicate (HfSiO₄), zirconium dioxide (ZrO₂), other hafnium-based compounds, and silicon oxynitride.

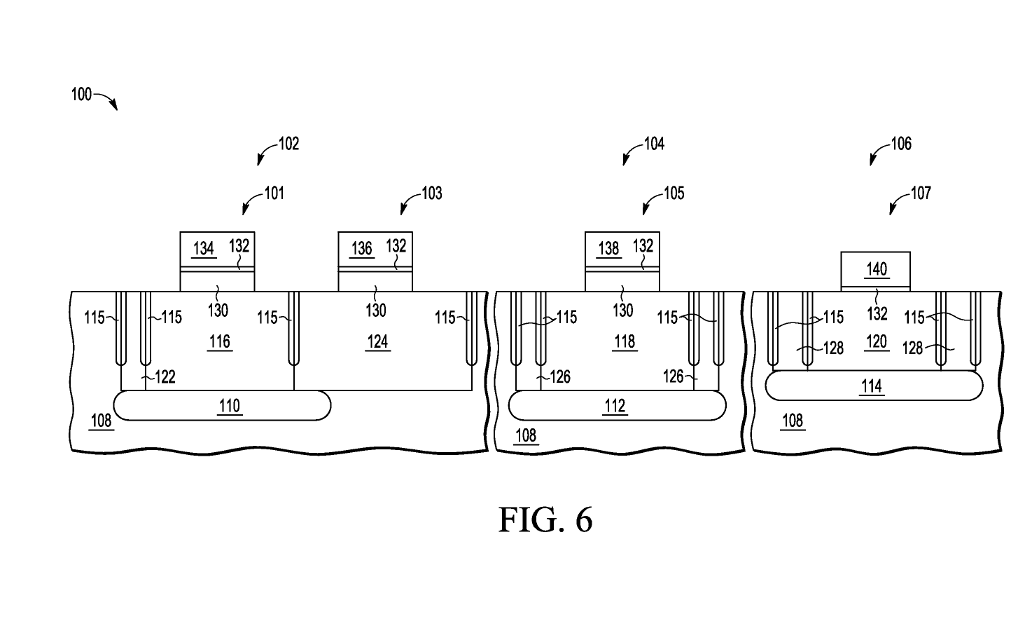

FIG. 6 illustrates, in cross-sectional form, semiconductor structure 100 at a subsequent processing stage, in accordance with one embodiment of the present invention. A conductive layer is deposited over high K dielectric layer 132 and subsequently patterned to form a first capacitor electrode 134 of a capacitor 101, a first capacitor electrode 136 of a capacitor 103, a gate electrode 138 of a HV transistor 105 (also referred to as a HV device), and a gate electrode 140 of a LV transistor 107 (also referred to as a LV device). Dielectric layers 130 and 132 are also pattered with the conductive layer. Capacitor electrode 134 is formed over PW 116 in which PW 116 corresponds to a second capacitor electrode of capacitor 101. A remaining portion of dielectric layers 132 and 130 between capacitor electrode 134 and PW 116 corresponds to the capacitor dielectric of capacitor 101 (also referred to as the dielectric region of capacitor 101). Capacitor electrode 136 is formed over NW 124 in which NW 124 corresponds to a second capacitor electrode of capacitor 103. A remaining portion of dielectric layers 132 and 130 between capacitor electrode 136 and NW 124 corresponds to the capacitor dielectric of capacitor 103 (also referred to as the dielectric region of capacitor 103). Therefore, note that capacitors 101 and 103 are coupled in series and are part of a capacitor module, such as capacitor module 20.

Still referring to FIG. 6, gate electrode 138 is formed over PW 118 and corresponds to the gate electrode of HV transistor 105, in which a remaining portion of dielectric layers 132 and 130 between gate electrode 138 and PW 118 corresponds to the gate dielectric of transistor 105 (also referred to as the dielectric region of transistor 105). Gate electrode 140 is formed over LVPW 120, in which a remaining portion of dielectric layer 132 between gate electrode 140 and LVPW 120 corresponds to the gate dielectric of transistor 107 (also referred to as the dielectric region of transistor 107). In the illustrated embodiment, transistors 105 and 107 are being formed as p-type transistors. However, regions 104 and 106 may include any number of p-type or n-type transistors, and therefore, in an alternate embodiment, transistors 105 and 107 may be n-type transistors. In this case, the conductivity of the wells would be opposite to what is illustrated. For example, wells 118 and 120 would be n-type wells.

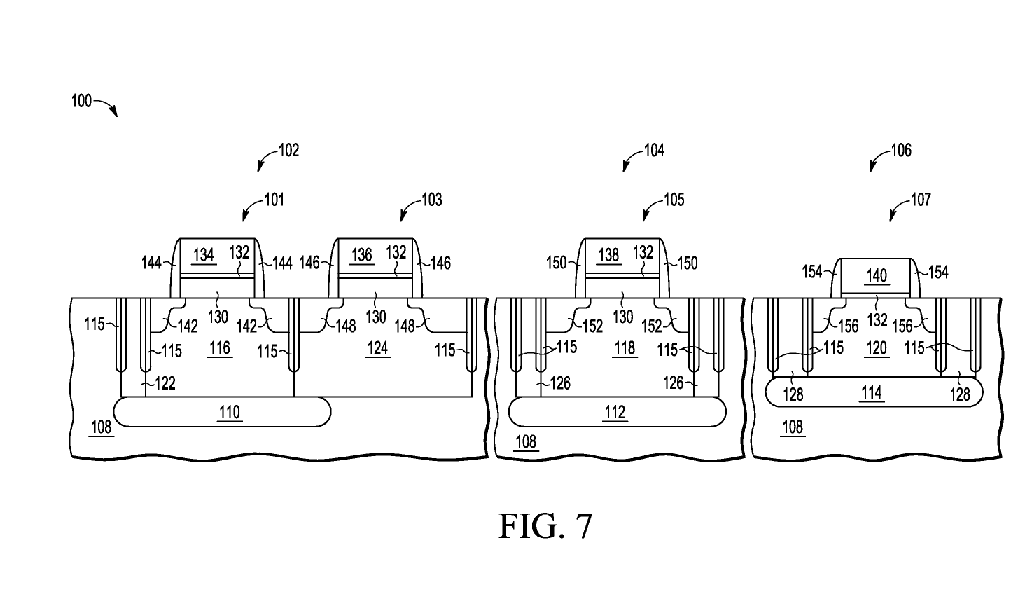

FIG. 7 illustrates, in cross-sectional form, semiconductor structure 100 at a subsequent processing stage, in accordance with one embodiment of the present invention. Sidewall spacer 144 is formed adjacent sidewalls of electrode 134 and underlying portions of dielectrics 132 and 130 corresponding to capacitor 101, sidewall spacer 146 is formed adjacent sidewalls of electrode 136 and underlying portions of dielectric 132 and 130 corresponding to capacitor 103, sidewall spacer 150 is formed adjacent sidewalls of electrode 138 and underlying portions of dielectrics 132 and 130 corresponding to transistor 105, and sidewall spacer 154 is formed adjacent sidewalls of electrode 140 and the underlying portion of dielectric 132 corresponding to transistor 107. To form the sidewalls, one or more layers of spacer material (e.g. dielectrics) may be deposited and then anisotropically etched. Source/drain regions 152 are formed in PW 118 and extend under spacer 150 and under a portion of gate electrode 138. Source/drain regions 156 are formed in LVPW 120 and extend under spacer 154 and under a portion of gate electrode 140. In one embodiment, after patterning of gate electrodes 138 and 140, shallow source/drain implants may be formed in substrate 108 to form the extension regions of source/drain regions 152 and 156, and after formation of spacers 150 and 154, deep source/drain implants may be formed in substrate 108 to complete the source/drain implants for source/drain regions 152 and 156. Note that during source/drain implants for p-type devices in regions 104 and 106, the n-type devices may be masked with a masking layer, and during source/drain implants for n-type devices in regions 104 and 106, the p-type devices may be masked with a masking layer. In regions 104 and 106, the source/drain implants have an opposite conductivity type to the well in which they are formed. For example, each of source/drain regions 152 and 156 are formed with n-type dopants.

In region 102, implant regions 142 and 148, similar in form to the source/drain regions in regions 104 and 106, are formed in wells 116 and 124. However, the conductivity type of the implants in region 102 is the same as the wells in which they are formed. For example, implant region 142 is formed with n-type dopants and implant region 148 is formed with p-type dopants. However, they may be formed using a shallow implant prior to formation of spacers 144 and 146 and a deep implant after formation of spacers 144 and 146, similar to the source/drain regions of regions 104 and 106. Also, since implant regions 142 and 148 are of different conductivity types, one well may be masked while the implants are performed in the other well. Furthermore, based on the implant types, the implants in region 102 may be formed at the same time as implants are formed in regions 104 and 106.

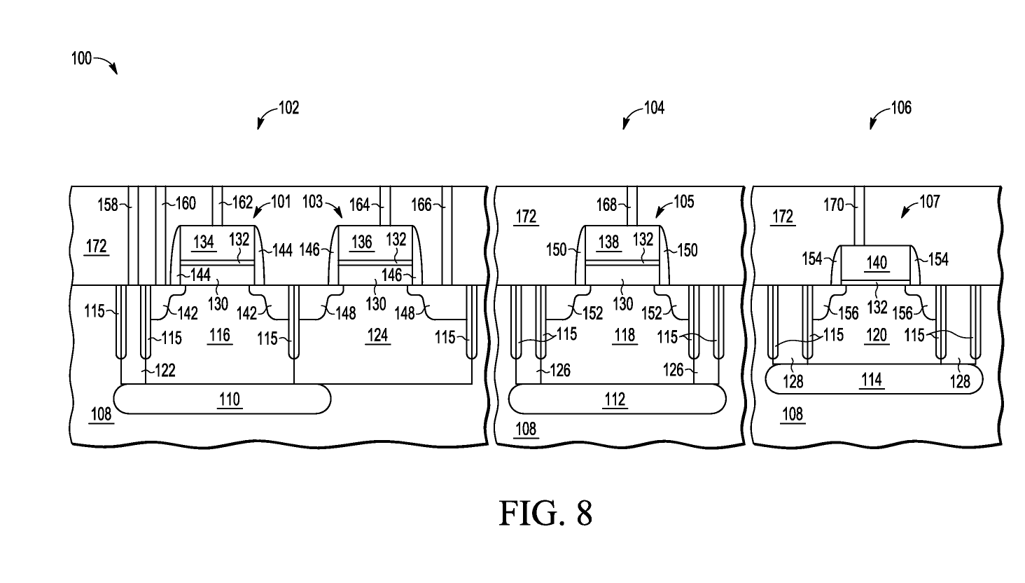

FIG. 8 illustrates, in cross-sectional form, semiconductor structure 100 at a subsequent processing stage, in accordance with one embodiment of the present invention. An interlayer dielectric layer (ILD) 172 is formed over substrate 108, capacitors 101 and 103, and transistors 105 and 107. Conductive vias are formed in ILD 172 to form contacts 158, 160, 162, 164, 166, 168, and 170. Contact 158 provides an electrical contact to NW 122, contact 160 provides an electrical contact to PW 116 and thus the second capacitor electrode of capacitor 101, and contact 162 provides an electrical contact to first capacitor electrode 134 of capacitor 101. Contact 166 provides an electrical contact to NW 124 and thus the second capacitor electrode of capacitor 103, and contact 164 provides an electrical contact to first capacitor electrode 136 of capacitor 103. Contact 168 provides an electrical contact to gate electrode 138, and contact 170 provides an electrical contact to gate 140. Note that additional contacts may be formed in ILD 172 to electrically contact other portions of capacitors 101 and 103 and transistors 105 and 107, other implant regions, or other wells, as needed.

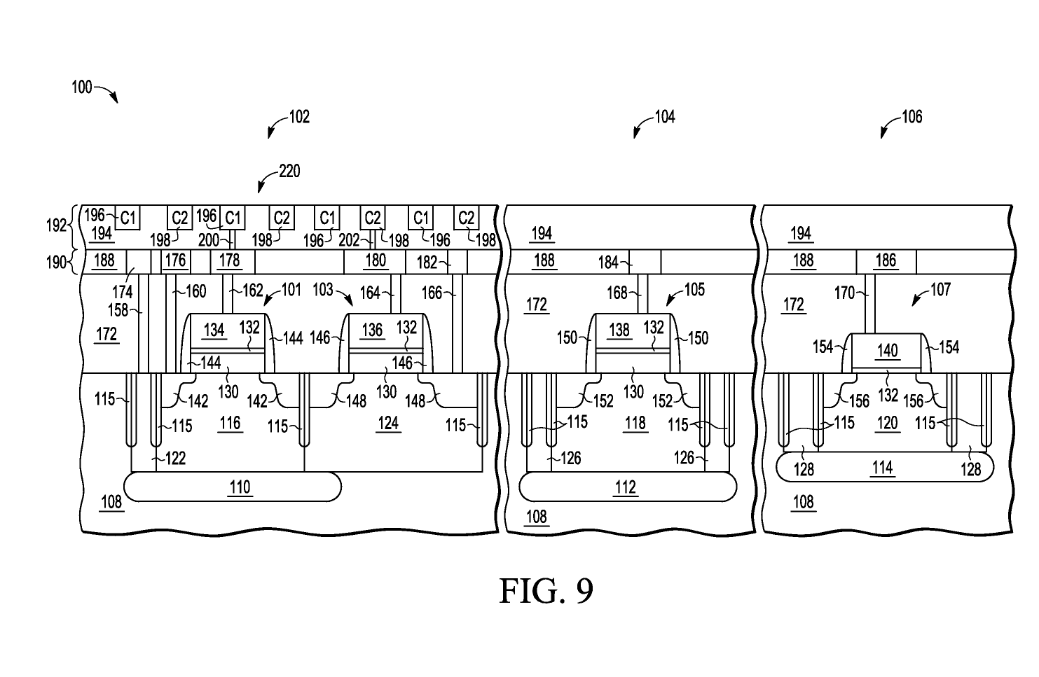

FIG. 9 illustrates, in cross-sectional form, semiconductor structure 100 at a subsequent processing stage, in accordance with one embodiment of the present invention. An interconnect layer 190 is formed over ILD 172 in regions 102, 104, and 106, and an interconnect layer 192 is formed over interconnect layer 190 in regions 102, 104, and 106. In one embodiment, interconnect layer 190 is formed by forming a dielectric layer 188 over ILD 172 in regions 102, 104, and 106, and then forming metal portions 174, 176, 178, 180, 182, 184, and 186 in dielectric layer 188, in which the metal portions extend from a top surface of dielectric layer 188 through to a bottom surface of dielectric layer 188 in order to contact an underlying contact in ILD 172. For example, metal portion 174 is in contact with contact 158, metal portion 176 is in contact with contact 160, metal portion 180 is in contact with contact 164, metal portion 182 is in contact with contact 166, metal portion 184 is in contact with contact 168, and metal portion 186 is in contact with contact 170. Contacts 160 and 166 may be electrically connected to each other to hold wells 116 and 124 at the same potential, or they may be biased to different potentials. Note that metal portions 174, 176, 178, 180, 182, 184, and 186 may include one or more metals such as copper or aluminum, or, alternatively, may be of a different conductive material. Also, metal portions 176, 178, 180, 182, 184, and 186 may be used to route signals within interconnect layer 190.

In one embodiment, interconnect layer 192 is formed by forming a dielectric layer 194 over interconnect layer 190 in regions 102, 104, and 106, and then forming metal portions 196 and 198 and conductive vias 200 and 202 in dielectric layer 194. Metal portions 196 and 198 correspond to a first capacitor comb C1 and a second capacitor comb C2 of a MOM capacitor 220, respectively. C1 is electrically connected to first capacitor electrode 134 of capacitor 101 by way of conductive via 200, and C2 is electrically connected to first capacitor electrode 136 of capacitor 103 by way of conductive via 202. In regions 104 and 106, interconnect layer 194 may include metal portions and conductive vias, as needed, to conduct signals, although none may be visible in the cross-section of FIG. 9.

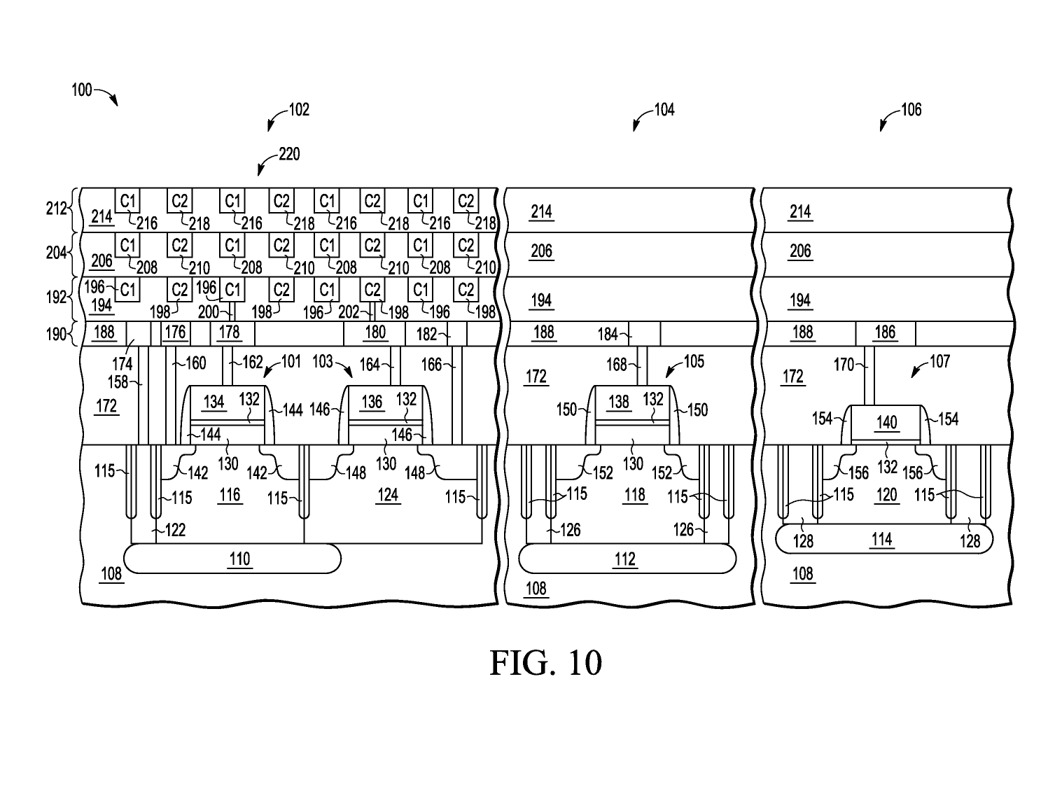

FIG. 10 illustrates, in cross-sectional form, semiconductor structure 100 at a subsequent processing stage, in accordance with one embodiment of the present invention. An interconnect layer 204 is formed over interconnect layer 192, and an interconnect layer 212 is formed over interconnect layer 204 in regions 102, 104, and 106. In one embodiment, interconnect layer 204 is formed by forming a dielectric layer 206 over interconnect layer 192 in regions 102, 104, and 106, and then forming metal portions 208 and 210 in dielectric layer 206. Metal portions 208 and 210 correspond to the first capacitor comb C1 and the second capacitor comb C2 of MOM capacitor 220, respectively. Metal portion 208 is electrically connected to metal portion 196 by way of one or more conductive vias formed in dielectric layer 206 which are not visible in the cross-section of FIG. 10. Also, metal portion 210 is electrically connected to metal portion 198 by way of one or more conductive vias formed in dielectric layer 206 which are not visible in the cross-section of FIG. 10.

In one embodiment, interconnect layer 212 is formed by forming a dielectric layer 214 over interconnect layer 204 in regions 102, 104, and 106, and then forming metal portions 216 and 218 in dielectric layer 214. Metal portions 216 and 218 correspond to the first capacitor comb C1 and the second capacitor comb C2 of MOM capacitor 220, respectively. Metal portion 216 is electrically connected to metal portion 208 by way of one or more conductive vias formed in dielectric layer 214 which are not visible in the cross-section of FIG. 10. Also, metal portion 216 is electrically connected to metal portion 210 by way of one or more conductive vias formed in dielectric layer 214 which are not visible in the cross-section of FIG. 10. Therefore, note that metal portions 216, 208, and 196 are all electrically connected to form C1 and metal portions 218, 210, and 198 are all electrically connected to form C2. C1 and C2 are formed using three interconnect layers of structure 10, however, in alternate embodiment, C1 and C2 of MOM capacitor 220 can be formed using any number (one or more) of interconnect layers. In regions 104 and 106, interconnect layers 204 and 212 may each include metal portions and conductive vias, as needed, to route signals, although none may be visible in the cross-section of FIG. 10.

Note that MOM capacitor 220 is formed over series-connected capacitors 101 and 103, and collectively, capacitors 220, 101, and 103 form a capacitor module, such as capacitor module 20 of FIG. 1. This stacked configuration results in horizontal area savings as compared to forming larger capacitors or laterally adjacent capacitors. Furthermore, the fingers of a comb of MOM capacitor 220 are aligned above each other in different interconnect layers. In this manner, when a voltage is applied to the combs, the combs of MOM capacitor 220 in each interconnect layer are at a same potential which allows for improved capacitive performance.

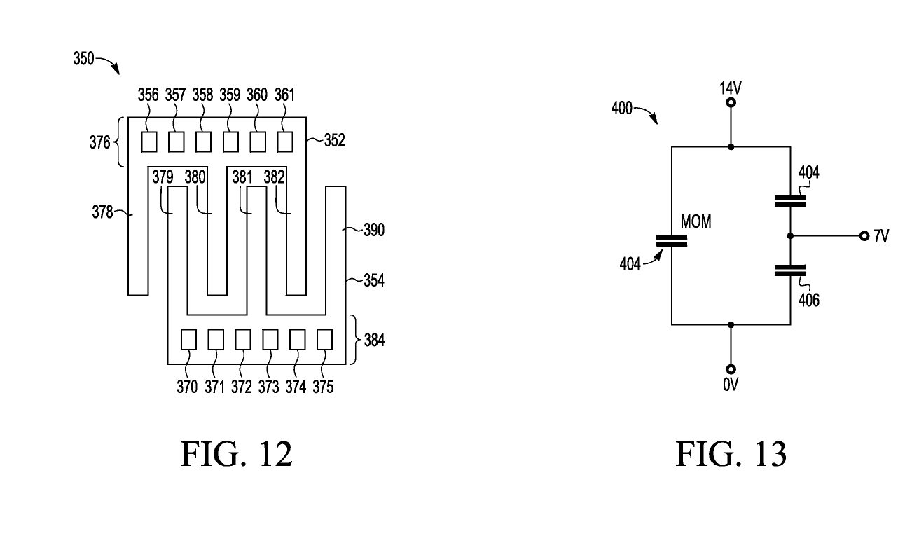

In the illustrated embodiment, MOM capacitor 220 is a fringe capacitor in which each of comb C1 and comb C2 includes four fingers formed in an interdigitated configuration. Therefore, MOM capacitor 220 includes four interdigitated fingers. FIG. 12 illustrates, a top down view, of an interdigitated fringe MOM capacitor 350 which includes a first comb 352 having fingers 378, 380, and 382 extending from a spine portion 376, and a second comb 354 having fingers 379, 381, and 390 extending from a spine portion 384. Unlike MOM capacitor 220 of FIG. 10, MOM capacitor 350 includes 3 interdigitated fingers rather than 4, but can be formed in a similar manner as MOM capacitor 220 using any number of interconnect layers. Also, MOM capacitor 220 may be formed including any number (2 or more) of interdigitated fingers. Conductive vias can be placed anywhere along the combs to form electrical connections to metal portions of the combs in underlying or overlying interconnect layers. In the embodiment of FIG. 12, conductive vias 356-361 are placed along spine portion 376 and conductive vias 370-375 are placed along spine portion 384. Note that these conductive vias and spine portions of MOM capacitor 220 are not visible in the cross-section of FIG. 10 but would be present within interconnect layers 194, 204 and 212.

FIG. 13 illustrates, in schematic form, a capacitive module 400 which includes a MOM capacitor 402 and series connected capacitors 404 and 406. Note that MOM capacitor 402 is connected in parallel with series connected capacitors 404 and 406. In this manner, when a high voltage, such as 14V, is applied across MOM capacitor 402, each of capacitors 404 and 406 see only a fraction of this voltage. In the illustrated embodiment, each of capacitors 404 and 406 are equally sized, thus seeing a voltage drop of half the total voltage across MOM capacitor 402 (7V). MOM capacitor 402 may correspond to MOM capacitor 220 of FIG. 10, and capacitors 404 and 406 may correspond to capacitors 101 and 103 of FIG. 10. Referring to the cross section of FIG. 10, note that contact 160 may be used to couple a first bias voltage to well 116 and contact 166 may be used to couple a second bias voltage to well 124. In this embodiment, a 7V bias may be applied to each of these wells such that the total of 14V is split across capacitors 101 and 103. Note that wells 116 and 124 correspond to the adjacent electrodes of capacitors 404 and 406 (the bottom electrode of capacitor 404 and the top electrode of capacitor 406), and can be biased to different levels so long as the voltage drop across each of capacitors 404 and 406 does not exceed the tolerance limits of the device. That is, capacitors 404 and 406 (and likewise, capacitors 101 and 103) need not be equally sized.

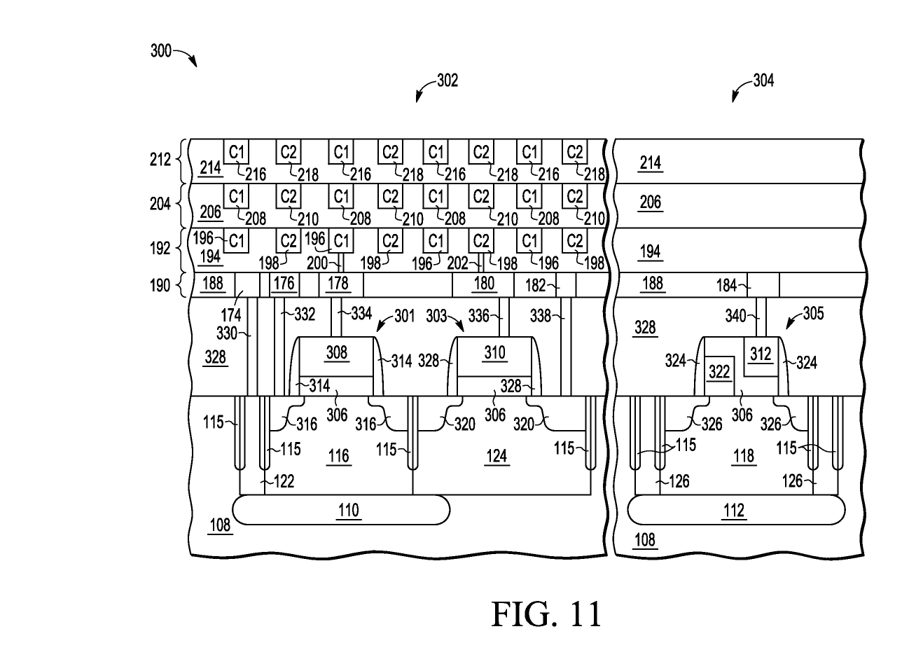

In the embodiments of FIGS. 2-10, capacitors 101 and 103 are formed using the available processing used for the formation of device 105 in HV region 104. That is, the dielectric layers used to form the gate dielectric of device 105 are also used to form the dielectric layers of capacitors 101 and 103. Therefore, the dielectrics of capacitors 101 and 103 have the same material composition as the gate dielectric of device 105. In other embodiments, capacitors 101 and 103 may be integrated using other layers used in forming other devices of the integrated circuit. For example, FIG. 11 illustrates, in cross-sectional form, a semiconductor structure 300 in which like numbers with FIGS. 2-10 indicate like elements. Semiconductor structure 300 includes a HV capacitor region 302 and a memory region 304. In region 304, a memory device 305 is formed on and in substrate 108. In the illustrated embodiment, memory device 305 is a split gate memory device having a select gate 322, a dielectric charge storage layer 306, a control gate 312, and a sidewall spacer 324. Select gate 322 is formed over well 118, dielectric 306 is formed over select gate 322 and extending laterally onto substrate 108, and control gate 312 is formed over dielectric 306 and adjacent to select gate 322 such that dielectric 306 is located between inner adjacent sidewalls of select gate 322 and control gate 312. Dielectric 306 may be any type of charge storage layer. For example, dielectric 306 may include a bottom oxide, a plurality of nanocrystals, and a top oxide that is over and surrounds the plurality of nanocrystals. Alternatively, dielectric 306 may include an oxide-nitride-oxide stack. Note that dielectric 306 may also be referred to as a dielectric region of split gate memory device 305. Sidewall spacer 324 is adjacent outer sidewalls of select gate 322 and control gate 312, surrounding select gate 322 and control gate 312. A metal portion 184 in interconnect layer 190 and a contact 340 in dielectric 328 provides an electrical contact to control gate 312.

Capacitors 301 and 303 are similar to capacitors 101 and 103, except that the dielectrics are formed in a different manner. During formation of capacitors 301 and 303, the same layer 306 used to form the gate dielectric of memory device 305 is used to form the capacitor dielectrics of capacitors 301 and 303. In this manner, the dielectrics of capacitors 301 and 303 have a same material composition as the dielectric of memory device 305. Therefore, during formation of capacitors 301 and 303 and memory device 305, dielectric layer 306 is simultaneously formed in regions 302 and 304. Dielectric layer 306 is then patterned, as needed, to form the dielectrics of capacitors 301 and 303 and the dielectric of memory device 305.

A capacitor designed to withstand a high voltage, such as 14 volts, that is integrated with logic devices requires a thicker dielectric, which may not be available in the processing parameters used to form other devices of the IC, such as the logic devices or memory devices. In this case, a capacitor with increased area is required to provide the required capacitance per area. However, it is undesirable to increase circuit area. Therefore, by now it can be understood how providing a MOM capacitor coupled in parallel and stacked over a two or more series connected capacitors can provide the required capacitance per area for the high voltage applications while using the processing parameters available during the formation of other devices of the integrated circuit. For example, the gate dielectric for the HV devices or the gate dielectric for memory devices may be used to form the dielectrics for the series connected capacitors.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Although the invention has been described with respect to specific conductivity types or polarity of potentials, skilled artisans appreciated that conductivity types and polarities of potentials may be reversed. For example, although n-channel devices are illustrated in regions 104 and 106, p-channel devices may be formed and the capacitors of the capacitor module may used the gate dielectric layer of these p-channel devices to form the capacitor dielectrics.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Some of the above embodiments, as applicable, may be implemented using a variety of different information processing systems having a variety of different layouts. For example, although FIG. 1 and the discussion thereof describe an exemplary architecture and layout, this exemplary architecture and layout is presented merely to provide a useful reference in discussing various aspects of the invention. Of course, the description of the architecture and layout has been simplified for purposes of discussion, and it is just one of many different types of appropriate architectures and layouts that may be used in accordance with the invention. Those skilled in the art will recognize that the boundaries between logic blocks are merely illustrative and that alternative embodiments may merge logic blocks or circuit elements or impose an alternate decomposition of functionality upon various logic blocks or circuit elements.

Although the invention is described herein with reference to specific embodiments, various modifications and changes can be made without departing from the scope of the present invention as set forth in the claims below. For example, the MOM capacitor of a capacitor module may have a different configuration, such as a spiral or checkerboard configuration. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

In one embodiment, a semiconductor device includes a capacitor module including: a semiconductor substrate of a first polarity, the substrate including a deep well of a second polarity, a first well of the first polarity over the deep well, a second well of the second polarity over at least a portion of the deep well; a first capacitor including the first well as a first electrode, a dielectric layer over the first electrode, and an electrically conductive layer as a second electrode over the dielectric layer; a second capacitor including the second well as a first electrode, a dielectric layer over the first electrode, and an electrically conductive layer as a second electrode over the dielectric layer, wherein the first capacitor is coupled in series with the second capacitor; and a metal-oxide-metal (MOM) capacitor overlaying and coupled in parallel with the first and second capacitors. The MOM capacitor includes a first metal finger coupled to a first voltage terminal and a second metal finger coupled to a second voltage terminal, wherein the first and second voltage terminals are coupled to receive voltages that are different from one another. In one aspect, the first well is directly adjacent the second well. In another aspect, the dielectric layer in the first and second capacitors includes an oxide layer and a high-k dielectric layer. In another aspect, the MOM capacitor is a fringe MOM that includes a first comb of fingers including the first finger and a second comb of fingers including the second finger. In another aspect, the semiconductor device further includes an array of non-volatile memory (NVM) cells; and a charge pump coupled between the capacitor module and the array of NVM cells. In another aspect, the semiconductor device further includes a high voltage transistor formed in a high voltage region of the substrate. In another aspect, the semiconductor device further includes a split-gate non-volatile memory cell in a memory region of the substrate, and the dielectric layer in the first and second capacitors and the split-gate NVM cell include a charge storage layer. In another aspect, the semiconductor device further includes a low voltage transistor formed in a low voltage region of the substrate. In yet a further aspect, the dielectric layer of the first and second capacitors is formed of a same material as a dielectric layer in a gate electrode of the high voltage transistor; and the second electrode of the first and second capacitors is formed of a same material as a metal layer in the gate electrode of the high voltage transistor.

In another embodiment, a processing system on a chip (SOC) includes analog circuitry; a sea of logic gates; a memory device coupled to the sea of logic gates, the memory device including: an array of memory cells; a charge pump coupled to supply a first voltage to the memory cells; a capacitor module coupled to the charge pump. The capacitor module includes a first capacitor including a first electrode formed as a first doped well region in a substrate; a second capacitor including a first electrode formed as a second doped well region in the substrate, the second capacitor is coupled in series with the first capacitor; a metal-oxide-metal (MOM) capacitor formed over the first and second capacitors and coupled in parallel with the first and second capacitors. In one aspect, the SOC further includes a first contact for coupling the first doped well region to a first bias voltage; a second contact for coupling the second doped well region to a second bias voltage. In another aspect, the SOC further includes a high voltage logic device in a high voltage region of the substrate; and a low voltage logic device in a low voltage region of the substrate. In a further aspect, the first and second capacitors include a second electrode, and the high and low voltage logic devices include a gate having a conductive layer, the conductive layer and the second electrode are formed of the same material. In another aspect, the first and second capacitors and the high voltage logic device include a dielectric region of a first material composition, and the low voltage logic device includes a dielectric region of a second material composition. In another aspect, the SOC further includes a memory region on the substrate including the array of memory cells, wherein the memory cells are split-gate memory cells, wherein a dielectric region in the split gate memory cells and a dielectric region in the first and second capacitors have a same material composition. In another aspect, the MOM capacitor is a fringe MOM capacitor that includes a first comb of fingers and a second comb of fingers interdigitated with the fingers of the first comb.

In yet another embodiment, a method of making a semiconductor device includes forming a first doped well region in a substrate for a first electrode of a first capacitor; forming a second doped well region in the substrate for a first electrode of a second capacitor; simultaneously forming a dielectric layer over the first and second doped well regions and at least one of a logic device and memory device in another region of the substrate; forming a conductive layer over the dielectric layer to simultaneously form a second electrode for the first and second capacitors and a portion of a control gate for the at least one of the logic device and the memory device; forming a third capacitor in an interconnect layer over the first and second capacitors, wherein the first and second capacitors are coupled in series and the third capacitor is coupled in parallel with the first and second capacitors. In one aspect, the third capacitor is a metal-on-metal (MOM) capacitor that includes a first comb of fingers and a second comb of fingers interdigitated with the fingers of the first comb. In another aspect, the method further includes forming a deep well region below the first doped well region and at least a portion of the second doped well region. In another aspect, the method further includes forming a first contact to couple the first doped well to a first bias voltage; and forming a second contact to couple the second doped well to a second bias voltage.

What is claimed is:

1. A semiconductor device comprising:
a capacitor module including:
a semiconductor substrate of a first polarity, the substrate including:
a deep well of a second polarity;
a first well of the first polarity over the deep well;
a second well of the second polarity over at least a portion of the deep well;
a first capacitor including the first well as a first electrode, a dielectric layer over the first electrode, and an electrically conductive layer as a second electrode over the dielectric layer;
a second capacitor including the second well as a first electrode, a dielectric layer over the first electrode, and an electrically conductive layer as a second electrode over the dielectric layer,
wherein the first capacitor is coupled in series with the second capacitor;
a metal-oxide-metal (MOM) capacitor overlaying and coupled in parallel with the first and second capacitors, the MOM capacitor including a first metal finger coupled to a first voltage terminal and a second metal finger coupled to a second voltage terminal, wherein the first and second voltage terminals are coupled to receive voltages that are different from one another.

2. The semiconductor device of claim 1 wherein:
the first well is directly adjacent the second well.

3. The semiconductor device of claim 1 wherein:
the dielectric layer in the first and second capacitors includes an oxide layer and a high-k dielectric layer.

4. The semiconductor device of claim 1 wherein:
the MOM capacitor is a fringe MOM that includes a first comb of fingers including the first finger and a second comb of fingers including the second finger.

5. The semiconductor device of claim 1 further comprising:
an array of non-volatile memory (NVM) cells; and
a charge pump coupled between the capacitor module and the array of NVM cells.

6. The semiconductor device of claim 1 further comprising:
a high voltage transistor formed in a high voltage region of the substrate.

7. The semiconductor device of claim 1 further comprising:
a split-gate non-volatile memory cell in a memory region of the substrate, and the dielectric layer in the first and second capacitors and the split-gate NVM cell include a charge storage layer.

8. The semiconductor device of claim 6 further comprising:
a low voltage transistor formed in a low voltage region of the substrate.

9. The semiconductor device of claim 6 wherein:
the dielectric layer of the first and second capacitors is formed of a same material as a dielectric layer in a gate electrode of the high voltage transistor; and
the second electrode of the first and second capacitors is formed of a same material as a metal layer in the gate electrode of the high voltage transistor.

10. A processing system on a chip (SOC) comprising:
analog circuitry;
a sea of logic gates;
a memory device coupled to the sea of logic gates, the memory device including:
an array of memory cells;
a charge pump coupled to supply a first voltage to the memory cells;
a capacitor module coupled to the charge pump, the capacitor module including:
a first capacitor including a first electrode formed as a first doped well region in a substrate;
a second capacitor including a first electrode formed as a second doped well region in the substrate, the second capacitor is coupled in series with the first capacitor;
a metal-oxide-metal (MOM) capacitor formed over the first and second capacitors and coupled in parallel with the first and second capacitors.

11. The SOC of claim 10 further comprising:
a first contact for coupling the first doped well region to a first bias voltage;
a second contact for coupling the second doped well region to a second bias voltage.

12. The SOC of claim 10 further comprising:
a high voltage logic device in a high voltage region of the substrate; and
a low voltage logic device in a low voltage region of the substrate.

13. The SOC of claim 12 wherein the first and second capacitors include a second electrode, and the high and low voltage logic devices include a gate having a conductive layer, the conductive layer and the second electrode are formed of the same material.

14. The SOC of claim 10 wherein the first and second capacitors and the high voltage logic device include a dielectric region of a first material composition, and the low voltage logic device includes a dielectric region of a second material composition.

15. The SOC of claim 10 further comprising:
a memory region on the substrate including the array of memory cells, wherein the memory cells are split-gate memory cells, wherein a dielectric region in the split gate memory cells and a dielectric region in the first and second capacitors have a same material composition.

16. The SOC of claim 10 wherein:
the MOM capacitor is a fringe MOM capacitor that includes a first comb of fingers and a second comb of fingers interdigitated with the fingers of the first comb.

17. A method of making a semiconductor device comprising:
forming a first doped well region in a substrate for a first electrode of a first capacitor;
forming a second doped well region in the substrate for a first electrode of a second capacitor;
simultaneously forming a dielectric layer over the first and second doped well regions and at least one of a logic device and memory device in another region of the substrate;
forming a conductive layer over the dielectric layer to simultaneously form a second electrode for the first and second capacitors and a portion of a control gate for the at least one of the logic device and the memory device; and
forming a third capacitor in an interconnect layer over the first and second capacitors, wherein the first and second capacitors are coupled in series and the third capacitor is coupled in parallel with the first and second capacitors.

18. The method of claim 15 wherein the third capacitor is a metal-on-metal (MOM) capacitor that includes a first comb of fingers and a second comb of fingers interdigitated with the fingers of the first comb.

19. The method of claim 15 further comprising:
forming a deep well region below the first doped well region and at least a portion of the second doped well region.

20. The method of claim 15 further comprising:
forming a first contact to couple the first doped well to a first bias voltage;
forming a second contact to couple the second doped well to a second bias voltage.
